(19) United States
(12) Patent Application Publication
(10) Pub. No.: US 2019/0364669 A1
(43) Pub. Date: Nov. 28, 2019

(54) METHOD FOR MANUFACTURING LIGHT EMITTING MODULE

(71) Applicant: NICHIA CORPORATION, Anan-shi (JP)

(72) Inventors: Takashi MATSUO, Komatsushima-shi (JP); Takahito NIKI, Anan-shi (JP)

(21) Appl. No.: 16/418,580

(22) Filed: May 21, 2019

(30) Foreign Application Priority Data
May 25, 2018 (JP) 2018-100326

(51) Int. Cl. H05K 3/34; B23K 1/00

(52) U.S. Cl. CPC H05K 3/3431; H01L 33/486; B23K 1/0016

(57) ABSTRACT

A method for manufacturing a light emitting module includes: providing a light emitting device; placing a joining member on a wiring of a wiring board, the joining member containing solder particles and flux containing at least one of a solvent and an active agent; mounting the light emitting device on the joining member; performing a first heating process in which the wiring board, the joining member, and the light emitting device are heated for a first heating time in a first temperature range that is higher than a prescribed temperature, and lower than a fusing point of the solder particles; and performing a second heating process for a second heating time in a second temperature range higher than the fusing point of the solder particles, the second heating time being shorter than the first heating time.

### CROSS-REFERENCE TO RELATED APPLICATIONS

This application claims priority to Japanese Patent Application No. 2018-100326 filed on May 25, 2018. The entire disclosure of Japanese Patent Application No. 2018-100326 is incorporated herein by reference.

### TECHNICAL FIELD

The present disclosure relates to a method for manufacturing a light emitting module.

### BACKGROUND ART

Light emitting modules have been known for which a light emitting device such as an LED (Light Emitting Diode), etc., that uses a semiconductor light emitting element (hereafter also called a “light emitting element”) is mounted on a wiring board.

This kind of light emitting module is formed by mounting the light emitting device on solder, etc., that is mounted on a wiring board, after which by fusing the solder by heating using a reflow furnace, etc., the wiring board and the light emitting device are joined (Japanese Laid-Open Patent Application Publication No. 2003-318530, for example).

### SUMMARY

The solder contains flux, and the flux contains a volatile component such as a solvent, etc. When heat is applied during joining, a reduction reaction occurs between an oxide film of a metal subject to joining and the flux. There are cases when moisture that was generated during this reduction reaction, or the volatile component such as the solvent in the flux, etc., remains within the solder. This remaining moisture or volatile component is a void, and by this kind of voids being formed, there are cases when a problem such as a decrease in joining properties, etc., occurs.

An embodiment of the present invention includes the following configuration.

A method for manufacturing a light emitting module comprising: providing a light emitting device having an upper surface including a light emitting surface, and a lower surface for which an external connection terminal is exposed with the external connection terminal being spaced apart from an edge part of the lower surface of the light emitting device; placing a joining member on a wiring of a wiring board, the joining member containing solder particles and flux containing at least one of a solvent and an active agent; mounting the light emitting device on the joining member on the wiring board; performing a first heating process in which the wiring board, the joining member, and the light emitting device are heated for a first heating time in a first temperature range that is higher than a prescribed temperature, and lower than a fusing point of the solder particles, the prescribed temperature being in a range from about 10° C. lower than a boiling point of the at least one of the solvent and the active agent to the boiling point; and after the first heating process, performing a second heating process in which the wiring board, the joining member and the light emitting device are heated for a second heating time in a second temperature range higher than the fusing point of the solder particles, the second heating time being shorter than the first heating time.

Accordingly, when joining the wiring board and the light emitting device using a fusible joining member that uses flux that contains solder particles, and at least one of a solvent and an active agent, it is possible to suppress the formation of voids within the joining member.

### BRIEF DESCRIPTION OF THE DRAWINGS

FIG. 1A is a schematic plan view showing an example of a light emitting module obtained using the method for manufacturing a light emitting module of an embodiment.

FIG. 1B is a schematic side elevational view of the light emitting module shown in FIG. 1A.

FIG. 1C is a schematic cross section view taken along a line IC-IC of the light emitting module shown in FIG. 1A.

FIG. 2A is a schematic perspective view showing an example of the light emitting device used in the method for manufacturing a light emitting module of the embodiment.

FIG. 2B is a schematic perspective view of the light emitting device shown in FIG. 2A seen from the lower surface side.

FIG. 2C is a schematic cross section view taken along a line IIC-IIC in FIG. 2A.

FIG. 3A is a schematic perspective view showing another example of the light emitting device used in the method for manufacturing a light emitting module of the embodiment.

FIG. 3B is a schematic perspective view of the light emitting device shown in FIG. 3A seen from the lower surface side.

FIG. 3C is a schematic cross section view taken along a line IIIC-IIIC in FIG. 3A.

FIG. 4 is a schematic enlarged view of a joining member used in the method for manufacturing the light emitting module of the embodiment.

FIG. 5 is a schematic cross section view for explaining a step of the method for manufacturing a light emitting module of the embodiment.

FIG. 6A is a graph showing an example of a temperature profile of the method for manufacturing a light emitting module of the embodiment.

FIG. 6B is a graph showing another example of a temperature profile of the method for manufacturing a light emitting module of the embodiment.

### DETAILED DESCRIPTION OF EMBODIMENT

A mode for embodying the present invention is explained hereafter while referring to the drawings. However, the mode shown hereafter shows an example of the method for manufacturing a light emitting module for realizing in specific form the technical concept of the present invention, and the present invention is not limited to the method for manufacturing a light emitting module according to the following embodiment.

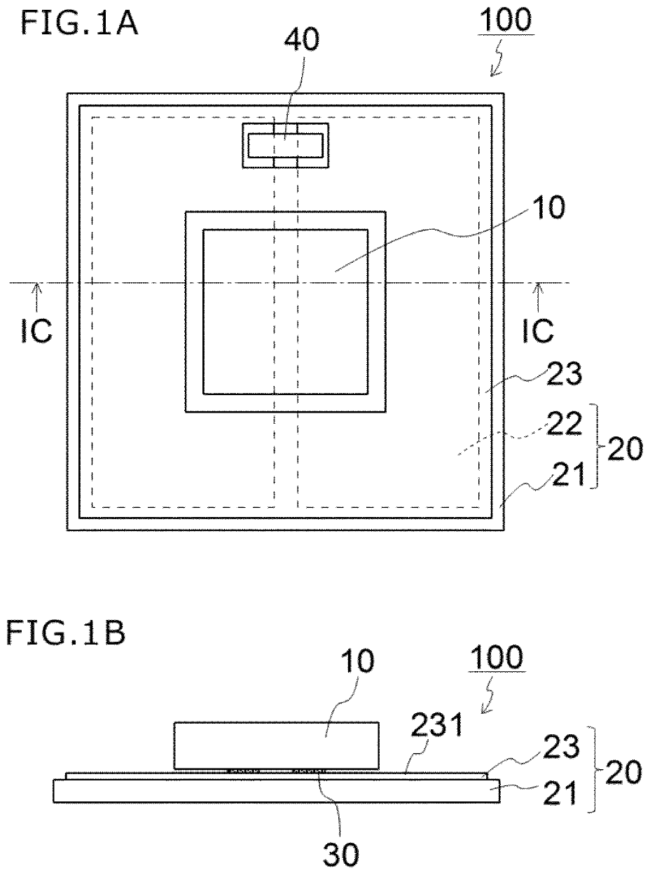

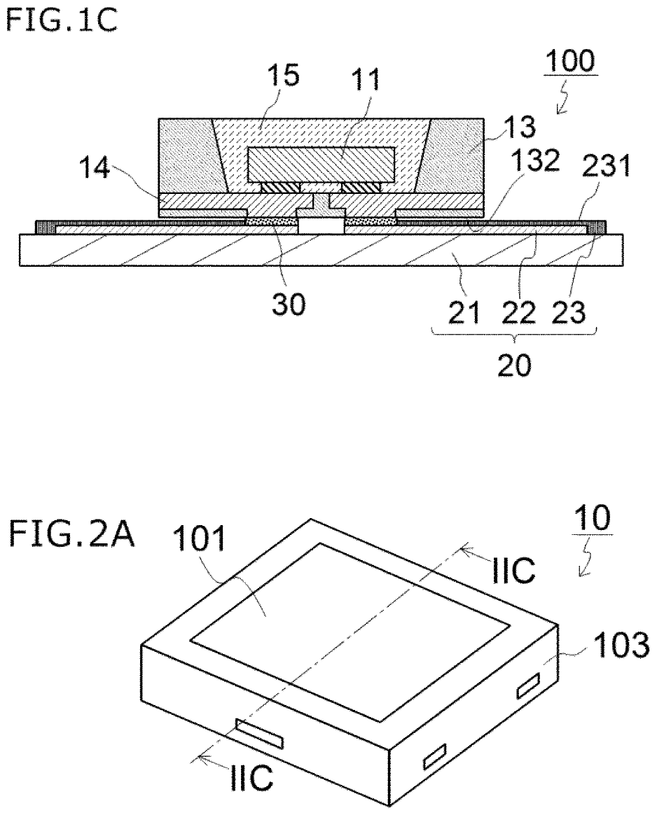

FIG. 1A is a schematic plan view showing an example of a light emitting module 100 obtained using the method for manufacturing a light emitting module of an embodiment. FIG. 1B is a schematic side elevational view of FIG. 1A. FIG. 1C is a schematic cross section view of FIG. 1A. The light emitting module 100 comprises a light emitting device 10, a wiring board 20, and a joining member 30 for joining the light emitting device 10 and the wiring board 20. An external connection terminal 14 is exposed at a lower surface 102 of the light emitting device 10. The external connection terminal 14 is placed separated from the edge part of the lower surface 102 of the light emitting device 10. The wiring board 20 comprises a base 21, and a wiring 22 placed on the upper surface thereof. The wiring 22 of the wiring board 20 and the external connection terminal 14 of the light emitting device 10 are fixed and electrically joined by the joining member 30. Also, a connector 40 for supplying power from a power supply may also be placed on the wiring 22. The connector 40 is connected on the wiring 22 that is exposed at a position separate from the light emitting device 10.

The method for manufacturing the light emitting module 100 like that described above includes a step of joining the light emitting device 10 and the wiring board 20 using the joining member 30 that contains flux and solder particles. The flux has rosin (resin) as a main component, and further contains at least one of an active agent, a solvent, a thixotropic agent (wax), etc. This step of joining the light emitting device 10 includes a step of heating and fusing the joining member 30, and in more detail, includes a first heating step and a second heating step. The first heating step is a step for heating in a first temperature range that is higher than a prescribed temperature around the boiling point of the solvent or the active agent contained in the flux and lower than the fusing point of the solder particles. The prescribed temperature is a temperature in a range from about 10° C. lower than the boiling point to the boiling point in consideration of temperature variations, etc. inside a heating equipment such as a reflow furnace. The second heating step is a step for, after the first heating step is performed, heating at a second temperature range that is higher than the fusing point of the solder particles. Also, a heating time T1 of the first heating step is longer than a heating time T2 of the second heating step. Said another way, the heating time T2 of the second heating step is shorter than the heating time T1 of the first heating step. With a method of heating using this kind of temperature profile, it is possible to suppress the formation of voids within the joining member 30.

Before the heating step, the joining member 30 contains a flux 32 and solder particles 31 as shown in FIG. 4. Also, after the heating step, the joining member 30 normally has all the solder particles fused and agglomerated. Then, a portion of the flux 32 is volatilized, and the flux 32 component that was not volatilized and remains covers the surface of the fused solder. In other words, the configuration of the joining member is not strictly the same before and after the heating step, but here, regarding the member that contains the solder material, the same name, “joining member,” is used before and after the heating step.

The void formed within the joining member is formed when gas generated by volatilization of the solvent, active agent, etc., contained in the flux by heating, or water generated by the reduction reaction between the flux and the oxide film of the metal that is subject to joining, is enclosed in the fused solder component. In other words, if flux is not contained to begin with, voids are not formed even if the solder material is fused. However, by the solder material containing flux, during heating, there is an effect exhibited of being able to remove and clean the oxide film, etc., of the solder particles surface and the surface of the metal that is subject to joining. By doing this, it is possible to do joining without a special condition such as having the environment during joining be a reducing atmosphere, etc. In other words, by containing flux, it is possible to join a metal material of wiring, etc., and the solder material in a normal atmosphere, or in a nitrogen atmosphere with nitrogen gas introduced in to a normal atmosphere.

With the method of this embodiment, by making the heating time long for the first heating step in which the solvent or active agent in the flux is volatilized without fusing the solder, first, cleaning of the wiring and external connection terminal surface, as well as the solder particles is performed by the flux, and it is possible to volatilize most of the solvent or active agent. With this first heating step, the solder particles are held in particle form without fusing. In other words, because the solvent or active agent in the flux is volatilized in a state held in a gap between the solder particles, the volatile component is easily discharged to outside via the gap between the solder particles.

Also, at the stage when the temperature is raised further and reaches the second temperature range that is higher than the fusing point of the solder material, the amount of the volatile component of the solvent or active agent in the flux remaining in the joining member is small, so enclosing of the volatile component of the solvent or the active agent on the interior when the solder particles are fused does not occur easily. In other words, voids are not formed easily.

As described above, in the first heating step, in a state with a discharge route for the volatile component of the solvent or the active agent contained in the flux ensured, the heating time is made longer so that sufficient cleaning of the wiring surface or the solder particles surface, etc. by the flux is possible. Also, in the subsequent second heating step, an oxide that is newly generated by fusing of the solder particles, for example the oxide of the metal that is subject to joining such as wiring, etc., is heated in the second temperature range for which the heating time is shorter, and by doing an oxidation reduction reaction with the residual flux, cleaning is done. By performing the heating step of the joining member with this kind of temperature profile, it is possible to have no generation of connection defects due to the oxide film, etc., and to suppress the occurrence of voids.

Furthermore, by making the heating time of the first heating step long, in a state when the content of the volatile component of the solvent or the active agent has become lower, it is preferable to have the temperature of the second heating step be higher than the fusing point of the solder material, and to have the heating time T2 be shorter. Furthermore, it is possible to have the temperature of the second heating step be a temperature that is lower than the temperature that is approximately 10° C. to 20° C. higher than the fusing point of the solder material. This is preferable because by doing this, it is possible to more efficiently suppress the occurrence of voids.

Typically, to suppress the occurrence of voids, a temperature profile is recommended that heats for a long time at a temperature range that exceeds the fusing point of the solder component. The temperature profile of the embodiment is effective when joining the light emitting device comprising the kind of external connection terminal described later, and is significantly different from the typical temperature profile.

Following is a detailed description of each step of the method for manufacturing a light emitting module.

### (Step for Providing a Light Emitting Device)

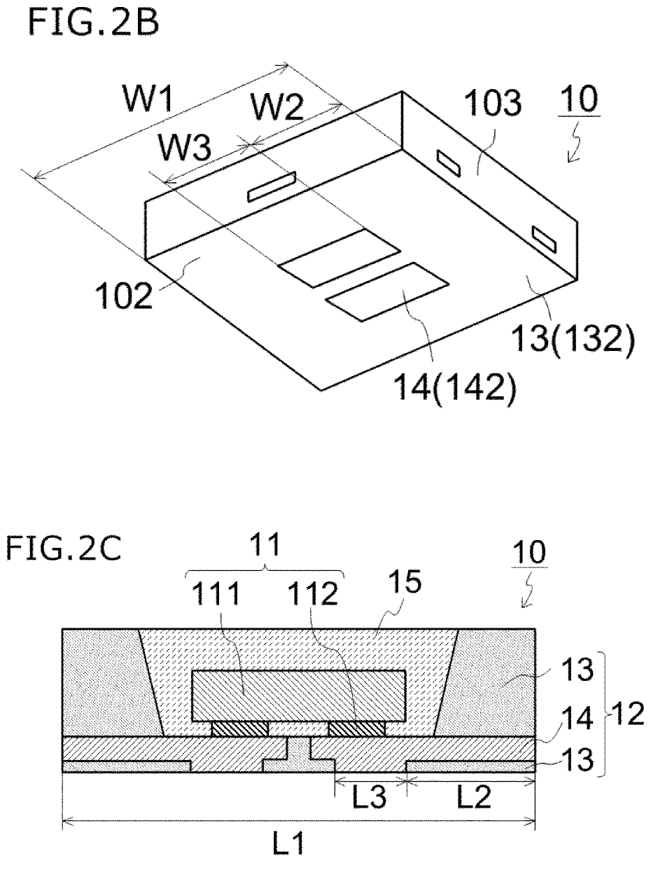

FIG. 2A to FIG. 2C are drawings showing an example of the light emitting device 10. The light emitting device 10 can be provided by purchasing, etc., the light emitting device 10 comprising the following configuration, or can be provided by performing part or all of the manufacturing steps.

The light emitting device 10 is a member that is the light source of the light emitting module 100, and comprises an upper surface 101 that comprises a light emitting surface, a lower surface 102 that includes a lower surface 142 of the external connection terminal 14, and a side surface 103 between the upper surface 101 and the lower surface 102. As shown in FIG. 2C, the light emitting device 10 comprises a package 12 that comprises a recess, a light emitting element 11 mounted inside the recess, and a light transmissive member 15 that seals the light emitting element 11. The package 12 comprises a substrate 13 with insulating properties, and the external connection terminal 14 that functions as an electrode.

The lower surface 102 of the light emitting device 10 is configured by a lower surface 132 of the substrate 13, and the lower surface 142 of the external connection terminal 14. The external connection terminal 14 is placed separated from the edge part of the lower surface 102 of the light emitting device 10. Said another way, the external connection terminal 14 is placed further to the inside than the outer circumference of the lower surface 102 of the light emitting device 10.

For example, as shown in FIG. 2B, a width W3 of the lower surface 142 of the external connection terminal 14 can be 30% to 80% of a width W1 of the lower surface 102 of the light emitting device 10. In FIG. 2B, the width W3 of the lower surface 142 of the external connection terminal 14 shows an example at approximately 55% of the width W1 of the lower surface 102 of the light emitting device 10. Also, as shown in FIG. 2C, a length L3 of the lower surface 142 of the external connection terminal 14 can be 15% to 40% of a length L1 of the lower surface 102 of the light emitting device 10. Here, this is the length L3 in the cross section view that sections both of a pair of external connection terminals 14, so the total width that adds the lengths L3 of the lower surfaces 142 of the two external connection terminals 14 is 30% to 80% of the length L1 of the lower surface 102 of the light emitting device 10.

The percentage of the lower surface 102 of the light emitting device 10 occupied by the lower surface 142 of the external connection terminal 14 is 10% to 70%. In this way, when the lower surface 142 of the external connection terminal 14 occupies a small surface area of the lower surface 102 of the light emitting device 10, since the amount of the joining member 30 is small to begin with, compared to cases when a large amount of the joining member is used, the effect of one void on the joining strength is great. For that reason, by performing the heating step with the temperature profile of this embodiment, it is possible to suppress a decrease in joining strength.

Also, a width W2 of the lower surface 132 of the substrate 13 between the edge part of the lower surface 102 of the light emitting device 10 and the lower surface 142 of the external connection terminal 14 is 20% to 70% of the width W1 of the lower surface 102 of the light emitting device 10. Also, a length L2 of the lower surface 132 of the substrate 13 between the edge part of the lower surface 102 of the light emitting device 10 and the lower surface 142 of the external connection terminal 14 is 10% to 35% of the length L1 of the lower surface 102 of the light emitting device 10. In this way, the lower surface 142 of the external connection terminal 14 is placed inward from the edge part of the lower surface 102 of the light emitting device 10, so the path through which the volatile component such as the solvent or the active agent contained in the flux or the water generated by the reduction reaction of the flux and the oxide film of the metal subject to joining, etc., is discharged is long. In such a case, compared to a case when the external connection terminal contacts the edge part in the lower surface of the light emitting device, or when placed in the vicinity of the edge part, the volatile component such as the solvent or the active agent contained in the flux, etc., or water, etc., is not easily discharged to outside. For that reason, voids are formed easily. By performing the heating step with the temperature profile of this embodiment, before the solder particles are fused, much of the flux 32 is volatilized, so it is possible to make it harder for voids to form when the solder particles are fused.

The lower surface 132 of the substrate 13 and the lower surface 142 of the external connection terminal 14 are roughly flush, or the lower surface 132 of the substrate 13 and the lower surface 142 of the external connection terminal 14 can be provided with a height difference of approximately 50 μm or less. As described above, when the lower surface 142 of the external connection terminal 14 is positioned substantially inward at the lower surface 102 of the light emitting device 10, the surface area for which the upper surface of the wiring board 20 and the lower surface 132 of the substrate 13 face opposite becomes large. Also, when an insulating film 23 of resist, etc., is formed on the wiring 22, an upper surface 231 of that insulating film 23 faces opposite the lower surface 132 of the substrate 13 at an extremely close distance. For that reason, furthermore, though the structure is such that the volatile component such as flux is not easily discharged to the outside, by performing the heating step with the temperature profile of this embodiment, it is possible to make it difficult for voids to be formed.

In FIG. 2A to FIG. 2C, the light emitting device 10 is shown by example as a resin package for which the substrate 13 is a resin material, and the external connection terminal 14 is a metal plate. The package 12 is not limited to this kind of configuration, and it is also possible to use a ceramic package for which the substrate 13 is ceramic, and the external connection terminal 14 is a wiring pattern. In addition to being the package 12 comprising a recess such as that shown in FIG. 2C, the package 12 can also be a flat plate-shaped package. The light emitting element 11 is placed on the upper surface of the external connection terminal 14 that is exposed at the inside of the recess, and is electrically connected with the external connection terminal 14 by a wire or an electrically conductive joining material.

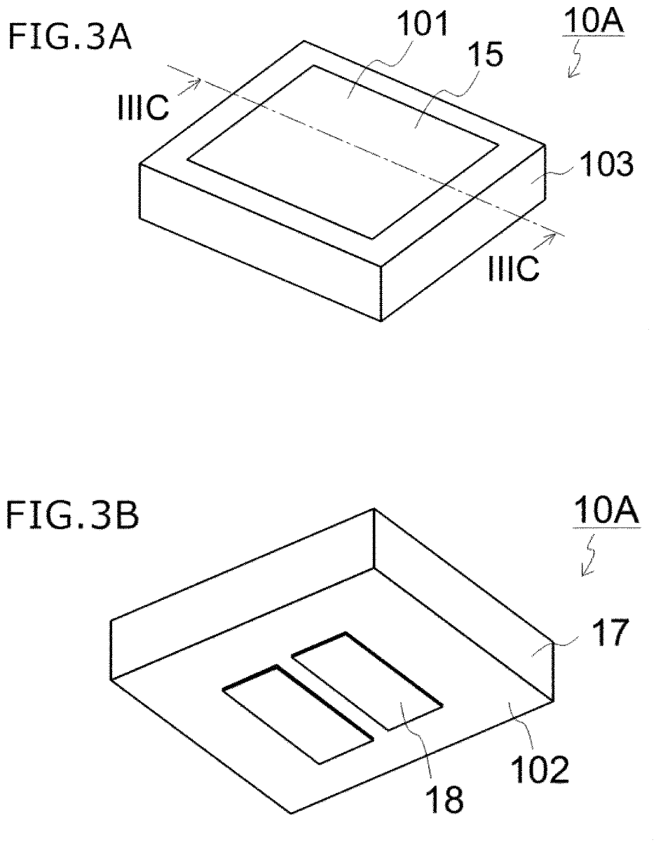

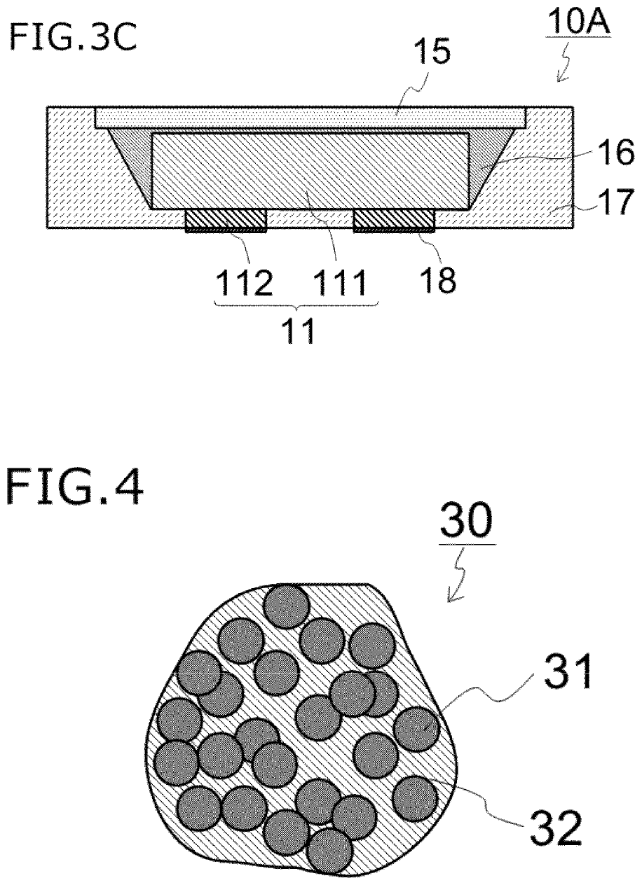

Furthermore, as the light emitting device, in addition to the light emitting device 10 comprising the package 12 like that described above, it is also possible to use a light emitting device 10A like that shown in FIG. 3A to FIG. 3C. With the light emitting device 10A, a metal film 18 that covers the lower surface of an element electrode 112 of the light emitting element 11 is exposed to the outside, and this metal film 18 functions as the external connection terminal. With the light emitting device 10A, a light guide member 16 is placed between the upper surface of the light emitting element 11 and the light transmissive member 15. The light guide member 16 is also placed at the side surface of the light emitting element 11. The side surface of the light emitting element 11 is covered by a covering member 17 with the light guide member 16 interposed. The covering member 17 is a resin material for protecting the light emitting element 11, etc., and is a member that correlates to the substrate 13 of the package 12 shown in FIG. 2A, etc.

With the light emitting device 10A as well, the same as with the light emitting device 10 shown in FIG. 2A, etc., at the lower surface 102 of the light emitting device 10A, the metal film (external connection terminal) 18 is separated from the edge part of the lower surface 102 of the light emitting device 10A. With the light emitting device 10A, the covering member (substrate) 17 and the metal film (external connection terminal) 18 are not flush, but rather the metal film 18 protrudes further downward than the covering member (substrate) 17. In a case of using the light emitting device 10A with this kind of configuration as well, the same as with the light emitting device 10 shown in FIG. 2A, etc., by performing the heating step with the temperature profile of this embodiment, it is possible to make it difficult for voids to be formed. In the light emitting device 10A shown in FIG. 3C, the light emitting element 11 and the light transmissive member 15 may be in contact, and the side surface of the light emitting element 11 and the covering member 17 may also be in contact without the light guide member 16 being interposed. It is also possible to have the light emitting device for which the metal film 18 is not provided, for which the element electrode 112 as is functions as the external connection terminal.

### (Step for Placing the Joining Member on the Wiring Board)

The step for placing the joining member on the wiring board can be performed before, at the same time, or after the step for providing the light emitting device.

The wiring board 20 comprises the base 21, and the wiring 22 placed on the upper surface of the base 21. Furthermore, it is also possible to comprise the insulating film 23 such as of resist, etc., that covers so that a portion of the wiring 22 is exposed. The wiring 22 comprises a mounting region exposed from the insulating film 23 at the position at which the light emitting device 10 is mounted. The mounting region can be a region of a size that is 100% to 150% with respect to the surface area of the lower surface 142 of the external connection terminal 14 of the light emitting device 10, and can have approximately the same shape. The wiring 22 surrounding this mounting region is covered by the insulating film 23. The wiring board 20 can use as the base 21 the base 21 having insulation properties such as ceramic, glass epoxy, paper phenol, etc., for example. Alternatively, as the base 21, it is also possible to use an electrically conductive base 21 using a metal such as aluminum, etc., and in that case, an insulation layer is provided between the electrically conductive base 21 and the wiring 22. Also, the shape of the wiring board 20 can be rectangular, circular, etc., for example. As the material of the wiring 22, it is possible to use Cu or Ag, for example. Furthermore, it is possible to use Au plating, solder plating, etc., on the surface of the wiring 22. Also, the wiring 22 may comprise water-soluble flux instead of the plating described above. For the insulating film 23, it is possible to use epoxy resin, silicone, etc., for example. The thickness of the insulating film 23 is preferably lower than the height of the joining member 30 after joining, and can be 5 μm to 30 μm, for example.

As shown in FIG. 4, the joining member 30 contains solder particles 31 and flux 32 covering the solder particles 31. As the solder particles 31, examples include a solder material such as of AuSn, SnAgCu, SnCu, SnZnBi, etc. The fusing point of the solder material, in the case of AnAgCu, for example, is 217° C. to 220° C. Also, as the flux 32, it is possible to use an item with rosin as the main component, that contains as additives an active agent or solvent, a thixotropic agent, etc. Of the flux components, the boiling point of the solvent or the active agent is around 200° C.

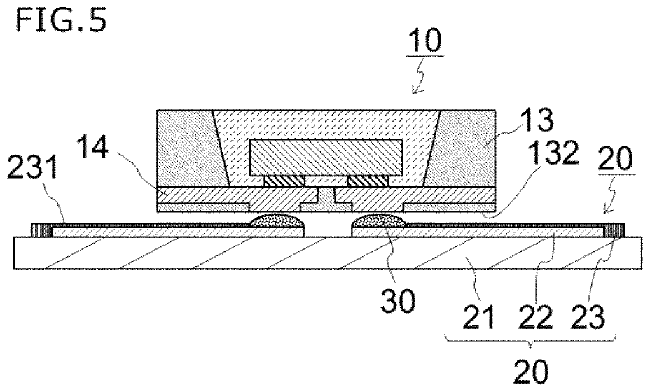

As shown in FIG. 5, this kind of joining member 30 is placed on the mounting region of the wiring 22. As a method for placing the joining member 30, it is possible to use printing application using a masking plate, dispensing using a dispensing nozzle, etc. The joining member 30 is preferably placed at 50% to 100% with respect to the surface area of the mounting region of the wiring 22 (opening of the insulating film 23). Also, the height of the joining member 30 before joining is preferably provided at a thickness greater than the thickness of the insulating film 23, for example. The joining member 30 has the volume reduced by fusing, and after joining, is configured only by solder, so it is preferable to consider that volume reduction amount. For example, the joining member 30 before joining can have a thickness of height 50 μm to 120 μm.

### (First Heating Step)

Next, the first heating step is performed. The first heating step is a step for heating in a first temperature range which is a temperature around the boiling point of the solvent or the active agent contained in the flux 32 or greater, and lower than the fusing point of the solder particles 31. First, as shown in FIG. 5, as the preparation step, the light emitting device 10 is mounted on the joining member 30 that is placed on the wiring board 20 so that the external connection terminal 14 is facing opposite. The external connection terminal 14 is separated from the edge part in the lower surface 102 of the light emitting device 10, so the lower surface 132 of the substrate 13 of the light emitting device 10 and the upper surface 231 of the insulating film 23 of the wiring board 20 are placed facing opposite. The insulating film 23 covers the wiring 22, so the height is higher than the upper surface of the wiring 22. In other words, the gap between the lower surface 132 of the substrate 13 of the light emitting device 10 and the upper surface 231 of the insulating film 23 is extremely narrow. For example, the gap between the lower surface 132 of the substrate 13 of the light emitting device 10 and the upper surface 231 of the insulating film 23 is 0.03 mm to 0.1 mm.

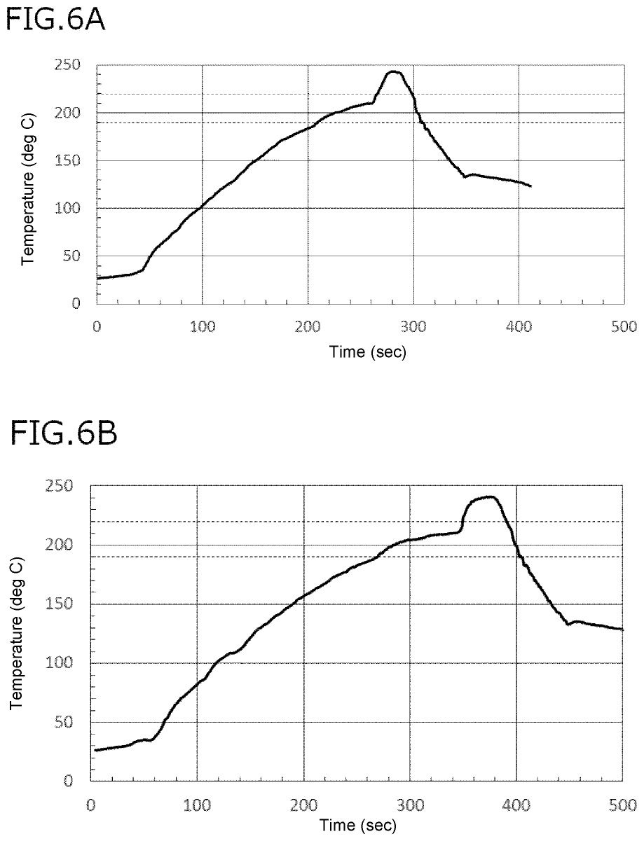

Next, the wiring board 20 and the light emitting device 10 placed thereon with the joining member 30 interposed are placed inside a heating equipment, and the first heating step is performed according to the temperature profile shown in FIG. 6A. The time it takes for the first heating step of heating in the first temperature range is heating time T1.

For example, when using flux for which the boiling point of the solvent or the active agent is approximately 200° C., and solder material for which the fusing point is approximately 220° C., the first temperature range is preferably a temperature range that is higher than 190° C. and lower than 220° C. Also, the heating time T1 of the first heating step can be 40 seconds to 100 seconds, for example.

### (Second Heating Step)

Next, the second heating step is performed. The second heating step is the step for heating at the second temperature range that is higher than the fusing point of the solder particles 31. The first heating step and the second heating step are performed successively within the same heating equipment. The time it takes for the second heating step of heating in the second temperature range is heating time T2.

For example, when using solder material with a fusing point of approximately 220° C., the second temperature range is preferably a temperature range between 220° C. or greater and lower than 240° C. Also, the heating time T2 of the second heating step can be 20 seconds to 50 seconds, for example.

FIG. 6A and FIG. 6B are graphs showing examples of temperature profiles when using flux for which the boiling point of the solvent or the active agent is approximately 200° C. and solder material for which the fusing point is approximately 220° C., as shown by example in the description above. In either case, starting from room temperature (approximately 25° C.), the temperature is gradually raised. In either case, the first temperature range T1 is in the range of 190° C. or greater and 220° C. or less, and the second temperature range T2 is in a range higher than 220° C. In FIG. 6A, the heating time T1 is 55 seconds, which is a period between 210 seconds and 265 seconds after heating start, and the heating time T2 is 33 seconds, which is a period between 265 seconds and 298 seconds after heating start. Also, in FIG. 6B, the heating time T1 is 80 seconds, which is a period between 265 seconds and 345 seconds after heating start, and the heating time T2 is 41 seconds, which is a period between 345 seconds and 386 seconds after heating start.

In this way, the heating time T1 of the first heating step is longer than the heating time T2 of the second heating step. By doing this, it is possible to suppress the formation of voids within the joining member 30 between the light emitting device 10 and the wiring board 20.

The overall heating time including the heating times T1 and T2 can be adjusted according to the amount of the joining member, etc. For example, FIG. 6A and FIG. 6B show the temperature profiles when using the same joining member, but when the amounts of the joining member used are different. More specifically, the example shown in FIG. 6A and the example shown in FIG. 6B are items for which the amount of solder used is changed, for example, with FIG. 6A being an example when the solder amount is small. As shown in FIG. 6B, both the heating times T1 and T2 are made longer as compared to the example shown in FIG. 6A. The first heating step is especially shorter in the example shown in FIG. 6A than the example shown in FIG. 6B.

What is claimed is:

1. A method for manufacturing a light emitting module comprising:
providing a light emitting device having an upper surface including a light emitting surface, and a lower surface for which an external connection terminal is exposed with the external connection terminal being spaced apart from an edge part of the lower surface of the light emitting device;
placing a joining member on a wiring of a wiring board, the joining member containing solder particles and flux containing at least one of a solvent and an active agent;
mounting the light emitting device on the joining member on the wiring board;
performing a first heating process in which the wiring board, the joining member, and the light emitting device are heated for a first heating time in a first temperature range that is higher than a prescribed temperature, and lower than a fusing point of the solder particles, the prescribed temperature being in a range from about 10° C. lower than a boiling point of the at least one of the solvent and the active agent to the boiling point; and
after the first heating process, performing a second heating process in which the wiring board, the joining member and the light emitting device are heated for a second heating time in a second temperature range higher than the fusing point of the solder particles, the second heating time being shorter than the first heating time.

2. The method for manufacturing a light emitting module according to claim 1, wherein
the fusing point of the solder particles is approximately 220° C.,
the boiling point of the at least one of the solvent and the active agent is approximately 200° C.,
the first temperature range is in a range higher than 190° C. and lower than 220° C., and
the second temperature range is in a temperature range higher than 220° C. and lower than 240° C.

3. The light emitting device according to claim 1, wherein
a width of a lower surface of the external connection terminal of the light emitting device is 30% to 80% of a width of the lower surface of the light emitting device.

4. The light emitting device according to claim 1, wherein
the wiring board includes an insulating film that defines an opening on the wiring, and
the placing of the joining member includes placing the joining member on the wiring of the wiring board through the opening in the insulating film.

5. The light emitting device according to claim 4, wherein
the placing of the joining member includes placing the joining member so that a thickness of the insulating film is lower than a height of the joining member.
